(19) United States
(12) Patent Application Publication
(10) Pub. No.: US 2011/0216512 A1
(43) Pub. Date: Sep. 8, 2011

(54) Low Cost PCB Carrier and Connectivity System For Enclosed Electronics

(76) Inventors: Ian VOSPER, Menlo Park, CA (US); Eugene Krzywinski, San Jose, CA (US); Troy Speers, Corralitos, CA (US)

(21) Appl. No.: 13/039,992

(22) Filed: Mar. 3, 2011

Related U.S. Application Data
(60) Provisional application No. 61/311,176, filed on Mar. 5, 2010.

(51) Int. Cl. H05K 5/00

(52) U.S. Cl. 361/756

(57) ABSTRACT

A low cost PCB carrier and connectivity system comprises a unique technique for securing a PCB within an enclosure, while providing electrical interconnection between wire cabling and/or other PCBs, without the use of screws.

### CROSS REFERENCE TO RELATED APPLICATIONS

This application claims priority to U.S. provisional patent application Ser. No. 61/311,176, filed Mar. 5, 2010, which is incorporated herein in its entirety by this reference thereto.

### BACKGROUND OF THE INVENTION

1. Technical Field

The invention relates to the securing of a printed circuit board (PCB) within an enclosure. More particularly, the invention relates to a low cost PCB carrier and connectivity system for enclosed electronics.

2. Description of the Background Art

Complex electrical systems, such a solar power systems, integrate cables and electronic assemblies, such as printed circuit boards (PCB), within an enclosure. The interconnection of these various components must be secure, efficient, and inexpensive. In this regard, it would be advantageous to address the integration of electrical busses within an enclosure, connectivity to electrical circuitry within the enclosure, and connectivity to integrated connectors that connect the busses and the internal circuitry to external conductors.

### SUMMARY OF THE INVENTION

The invention addresses the integration of electrical busses within an enclosure, connectivity to electrical circuitry within the enclosure, and connectivity to integrated connectors that connect the busses and the internal circuitry to external conductors.

### BRIEF DESCRIPTION OF THE DRAWINGS

FIG. 1 is a side, elevation view of an insulating support carrier according to the invention;

FIG. 2 is a top, plan view showing an insulating support carrier according to the invention;

FIG. 3 is side, elevation view showing a base of enclosure according to the invention;

FIG. 4 is perspective view of an insulating support carrier according to the invention;

FIG. 5 is a side, elevation view showing electrical contacts according to the invention;

FIG. 6 is a front, elevation view showing the electrical contacts according to the invention;

FIG. 7 is a perspective view showing the contacts crimped according to the invention;

FIG. 8 is front, elevation view showing an electrical contact base according to the invention;

FIG. 9 is a perspective view showing an example of a complete insulating support carrier according to the invention;

FIG. 10 is an enlarged, partial perspective view of the top left hand portion of the insulating support carrier shown in FIG. 9;

FIG. 11 is top, plan view showing an example of a printed circuit board according to the invention;

FIG. 12 is a side, elevation view of the insulating support carrier according to the invention; and

FIG. 13 is an exploded, perspective view showing an example of cabling and localized insulator stripping for crimping and connectivity according to the invention.

### DETAILED DESCRIPTION OF THE INVENTION

An embodiment of the invention provides a low cost printed circuit board (PCB) carrier and connectivity system. One aspect of the invention comprises a unique technique for securing a PCB within an enclosure, while providing electrical interconnection between wire cabling and/or other PCBs, without the use of screws.

In an embodiment, the connectors and cables are secured to a non-conductive insulating carrier that is self aligning to the base of an enclosure or other such mounting holder. The PCB is then secured to the insulating carrier through locking standoffs that are guided into correct alignment via locator pins on the insulating carrier and mating apertures formed in the PCB. In an embodiment, the electrical contacts are mounted onto the insulating carrier using non-conductive electrical contact bases. Wires, for example, within one or more cables, are stripped of their insulation at any point thereof comprising the electrical contact point, and electrical and mechanical connection is made to the electrical contacts by crimping the contacts to the wires. The other end of the electrical contact is a blade structure that makes electrical connection to the PCB through self aligning vias, which may then be soldered to the electrical contacts and which make electrical contact to traces on the PCB, or the blade structure may pass thought the via into a contact mounted and soldered to the PCB traces above the via. Multiple PCBs can be interconnected by either varying the length of the standoffs and the bladed part of the electrical contact, or soldering blade structure contacts to the trace of a PCB and having it pass through a self aligning via on another PCB either above or below.

In another embodiment, securing of the PCB, insulating carrier, and the enclosure is achieved by placing a cover having PCB locking posts on the inside of the enclosure.

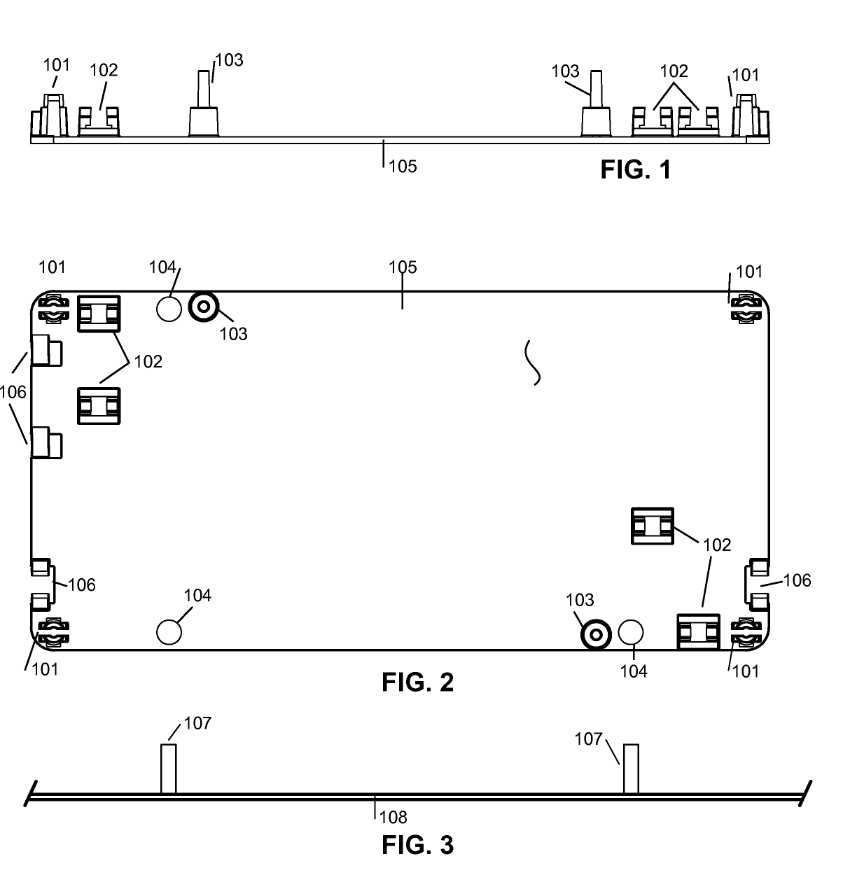

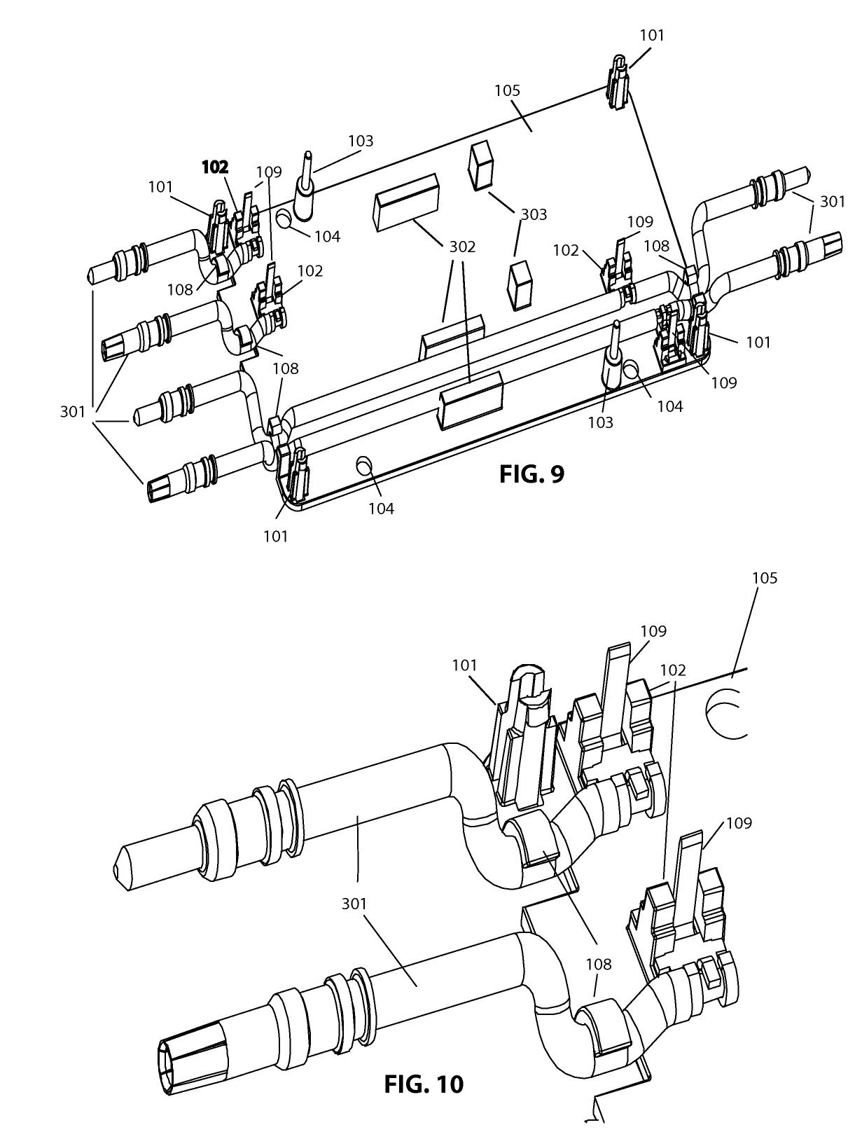

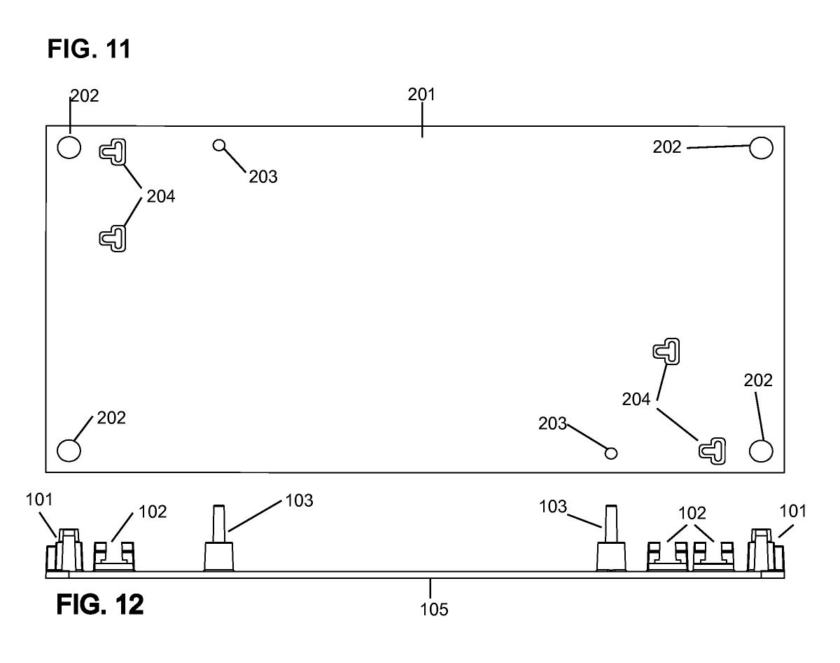

FIG. 1 is a side, elevation view of an insulating support carrier. FIG. 1 shows a PCB standoff and secure lock (101) that engages through a corresponding aperture (202) formed in a printed circuit board (PCB) (201) (see FIG. 11), and that locks the PCB in place. The PCB standoff and secure lock retains the PCB securely in place and also provides a mechanism for assuring correct alignment of the PCB. The top of the standoff (101) also engages with a board lock on the enclosure lid, which also provides a secure lock that holds the PCB firmly in place once the unit is assembled. The electrical contact base (102) provides a receptacle for the electrical connector (109) between one or more wires (301) (see FIG. 9) and PCB contact points (204) (see FIG. 11). The electrical contact base provides stability of connection and correct alignment between the wires and the PCB connection points. PCB locator pins (103) provide correct alignment of the PCB and correspond to respective locator holes (203) (see FIG. 11) formed in the PCB (201) (see FIG. 11). In an embodiment, the locator pins align and engage before the PCB standoffs (101) engage.

FIG. 2 is a top, plan view showing an insulating support carrier. In an embodiment, the carrier (105) is made of a non-conductive material, e.g. plastic, for lowest cost, although those skilled in the art will appreciate that other materials may be used. The carrier (105) is placed into the enclosure which contains pins or studs (107) (see FIG. 3). In an embodiment, there are three alignment holes (104) to ensure correct orientation of insulating support carrier to enclosure. Cable locks (106) provide a mechanism for strain relief and for securing wires to the insulating support carrier for electrical connection beyond the insulating support carrier.

FIG. 3 is side, elevation view showing a base of enclosure (108) including alignment pins (107).

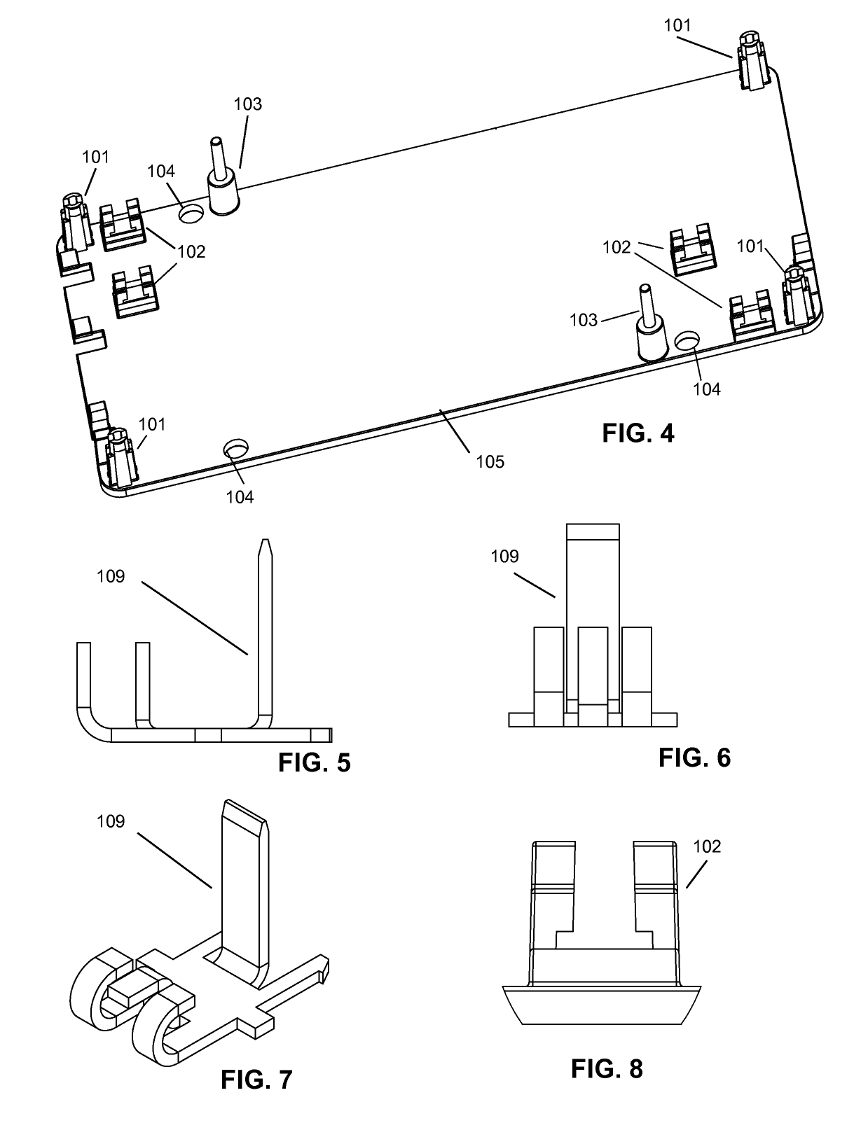

FIG. 4 is perspective view of an insulating support carrier, showing PCB standoff and secure locks (101), electrical contact bases (102), PCB locator pins (103), cable locks (106), and enclosure base alignment apertures (104).

FIG. 5 is a side, elevation view showing electrical contacts (109) for secure connection to wires (301) and PCB (201). FIG. 6 is a front, elevation view showing the electrical contacts. These contacts are crimped, as shown in FIG. 7, to secure the wire and make an electrical connection between the wire (301) and the PCB (201). FIG. 8 is front, elevation view that shows an electrical contact base (102). The provision of a rectangular blade ensures correct alignment and prevents connection in any other orientation (see FIGS. 9 and 10).

FIG. 9 is a perspective view showing an example of a complete insulating support carrier, including wires (301) fastened to the insulating support carrier (108) and connected to electrical contacts (109) that are fastened to their respective electrical contact bases (102). Structures (302) and (303) are wire guides and spacers in this example, where the PCB has heavy magnetic components mounted directly over these guides and spacers.

FIG. 10 is an enlarged, partial perspective view of the top left hand portion of the insulating support carrier shown in FIG. 9.

FIG. 11 is top, plan view showing an example of a printed circuit board, i.e. PCB (201). The PCB (201) is secured via the PCB standoff and secure lock (101) through apertures (202). In some embodiments, once the PCB (201) is secured by pressing the PCB firmly onto the PCB standoff and secure locks (101), a commonly used tool known to those skilled in the art (not shown) is required to unmount the PCB from the PCB standoff and secure locks. Electrical connectivity is provided to any of wires, other PCBs, or other traces by a plurality of vias (204). PCB traces are normally connected to the vias points and routed on the surface of the PCB, which may also contain other devices and connectors.

FIG. 12 is a side, elevation view of the insulating support carrier (105) showing the relation of the standoffs (101), PCB locator pins (103), and electrical contact bases (102) to their counterparts on the PCB (201).

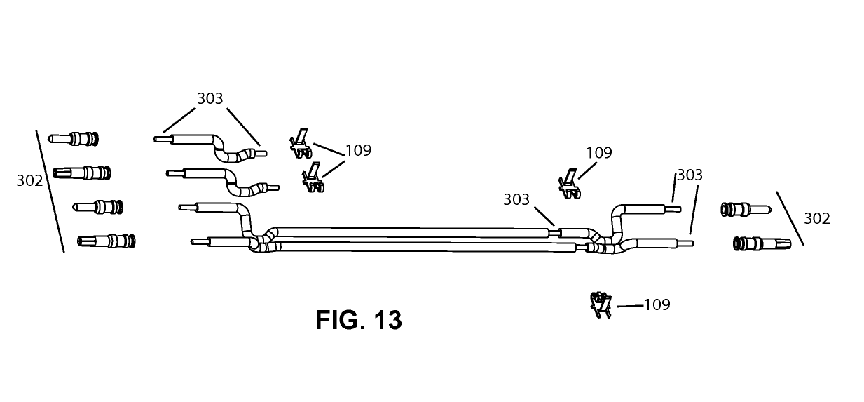

FIG. 13 is an exploded, perspective view showing an example of cabling and localized insulator stripping for crimping and connectivity. Wires (301) have their insulation removed and the uninsulated portion (303) is inserted into the electrical contact (109) where the electrical contact (109) is then crimped. The wires may terminate at either an electrical contact (109) or at connectors (302) that are specific to the application.

Although the invention is described herein with reference to the preferred embodiment, one skilled in the art will readily appreciate that other applications may be substituted for those set forth herein without departing from the spirit and scope of the present invention. Accordingly, the invention should only be limited by the Claims included below.

1. An apparatus for securing a printed circuit board (PCB), comprising:
an insulating carrier that is self aligning to a base;
a plurality of locator pins mounted on, and projecting from, a first surface of said insulating carrier, said locator pins arranged for guiding said PCB into position by mating alignment with complementary apertures formed in said PCB;
a plurality of locking standoffs mounted on, and projecting from, said first surface of said insulating carrier, said locking standoffs configured for securing said PCB to said insulating carrier through secure engagement thereof with complementary apertures formed in said PCB; and
a plurality of electrical contact bases mounted on said insulating carrier.

2. The apparatus of claim 1, wherein said insulating carrier is non-conductive.

3. The apparatus of claim 1, wherein said base comprises an enclosure.

4. The apparatus of claim 1, each of said electrical contact bases defining an engagement and connection portion that is configured to receive, retain, and maintain an electrical connection with a respective electrical contact.

5. The apparatus of claim 4, each said electrical contact comprising at least one crimp tang for maintaining electrical and mechanical connection with a respective wire.

6. The apparatus of claim 4, each said electrical contact comprising a substantially rectangular contact blade for maintaining correct alignment and preventing connection in any other than an intended orientation.

7. The apparatus of claim 1, said PCB comprising:
a plurality of through self-aligning vias that are each arranged on said PCB to correspond with respective electrical contacts on said insulating carrier to make an electrical connection between said electrical contacts and respective traces on said PCB.

8. The apparatus of claim 6, wherein a selected length of said standoffs and said electrical contact blade determines a number of PCBs that can be interconnected.

9. The apparatus of claim 1, further comprising:
a cover comprising a plurality of locking posts positioned thereon to secure said PCB, insulating carrier, and enclosure through mating engagement of said locking posts with corresponding complementary locking posts positioned on an inside of said enclosure.

10. The apparatus of claim 1, an upper portion of said standoff comprising an engagement member for mating engagement with a complementary board lock provided on an enclosure lid.

11. The apparatus of claim 1, said insulating carrier comprising three locator pins.

12. The apparatus of claim 1, said insulating carrier further comprising:
a plurality of cable locks configured for providing strain relief and for securing wires to said insulating carrier for electrical connection beyond said insulating carrier.

13. An apparatus for securing a printed circuit board (PCB), comprising:
a non-conductive, insulating carrier;
a plurality of locator pins mounted on, and projecting from, a first surface of said insulating carrier, said locator pins arranged for guiding said PCB into position by mating alignment with complementary apertures formed in said PCB; and
a plurality of locking standoffs mounted on, and projecting from, said first surface of said insulating carrier, said locking standoffs configured for securing said PCB to said insulating carrier through secure engagement thereof with complementary apertures formed in said PCB.

14. The apparatus of claim 13, further comprising:
a plurality of electrical contact bases mounted on said insulating carrier, each of said electrical contact bases defining an engagement and connection portion that is configured to receive, retain, and maintain an electrical connection with a respective electrical contact, each said electrical contact comprising at least one crimp tang for maintaining electrical and mechanical connection with a respective wire, each said electrical contact comprising a substantially rectangular contact blade for maintaining correct alignment and preventing connection in any other than an intended orientation.
